(19) United States
(12) Patent Application Publication
(10) Pub. No.: US 2005/0057903 A1
(43) Pub. Date: Mar. 17, 2005

(54) Cooling structure for electronic element

(76) Inventor: Kee-Hoon Choi, Seoul (KR)

Correspondence Address: MORGAN, LEWIS & BOCKIUS, LLP., 2 PALO ALTO SQUARE, 3000 EL CAMINO REAL, PALO ALTO, CA, 94306, US

(21) Appl. No.: 10/749,206

(22) Filed: Dec. 30, 2003

(30) Foreign Application Priority Data
Sep. 16, 2003 (KR) 10-2003-0063971

(51) Int. Cl. H05K 7/20

(52) U.S. Cl. 361/719

(57) ABSTRACT

A cooling structure for an electronic element is disclosed in which smooth heat transfer can be carried out via a variety of heat transfer routes of conduction and convention without recourse to a forced cooling means such as a fan or the like, thus improving the cooling performance of electronic elements and stabilizing the operation of electronic circuits for a long period of time.

### CROSS-REFERENCE TO RELATED APPLICATIONS

This application claims priority of Korean Application No. 10-2003-0063971, filed on Sep. 16, 2003, the disclosure of which is incorporated fully herein by reference.

### FIELD OF THE INVENTION

The present invention relates to a cooling structure for an electronic element mounted on an electronic circuit substrate and, more particularly, to a technology relating to more effective cooling of an element that generates a large amount of waste heat.

### BACKGROUND OF THE INVENTION

There has been a recent trend to integrate a plurality of electronic elements in a single package. For proper performance, electronic elements that generate waste heat must be cooled to an optimal temperature. In particular, in order for a Code Division Multiple Access (CDMA) modem to operate for an extended period, there must be optimal cooling of a Power Amplifying Module (PAM) comprising the CDMA modem.

### SUMMARY OF THE INVENTION

Embodiments of the present invention provide an improved cooling structure for a heat-producing electronic element mounted on a circuit substrate to ensure stable performance of the electronic element for an extended period.

In accordance with a preferred embodiment of the present invention, the cooling structure for a heat-producing electronic element comprises an extended portion formed on an inner baffle, with the inner baffle located on the perimeter of an inner circuit substrate. The extended member also contacts an upper surface of the heat-producing electronic element. The heat-producing electronic element is mounted on the inner circuit substrate. A plurality of through holes are formed at the inner circuit substrate underneath the heat-producing electronic element, which may be a PAM. A radiating plate is mounted on a baffle case surrounding the outside of the inner bafflement and the inner circuit substrate. A plurality of baffle case holes is formed underneath the baffle case.

### BRIEF DESCRIPTION OF THE DRAWINGS

For a fuller understanding of the nature and objectives of the present invention, reference should be made to the following detailed description taken in conjunction with the accompanying drawings in which:

FIG. 1 is a cross-sectional view for illustrating a cooling structure for an electronic element;

FIG. 2 is a plan view of an inner bafflement and an extension thereof of FIG. 1;

FIG. 3 is a plan view of baffle case holes formed underneath the baffle case of FIG. 1;

FIG. 4 illustrates the surface of an external circuit substrate to be cooled; and

FIG. 5 is a detailed drawing of through holes of the cooling structure of FIG. 1.

### DETAILED DESCRIPTION OF THE PREFERRED EMBODIMENTS

The preferred embodiment of the present invention will now be described in detail with reference to the accompanying drawings.

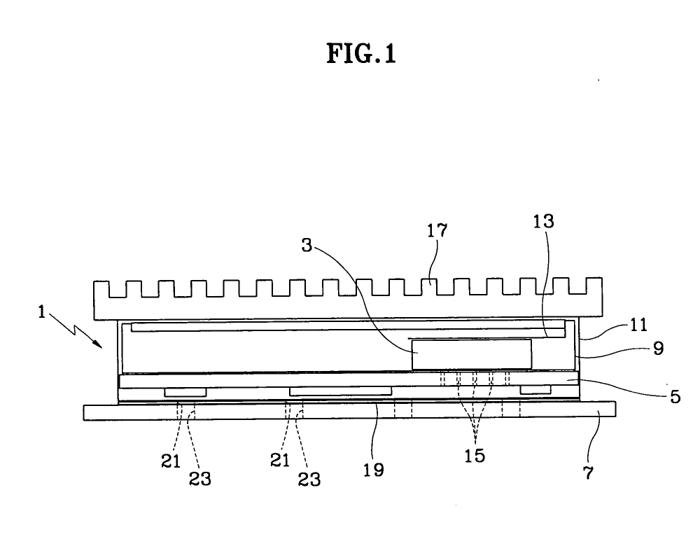

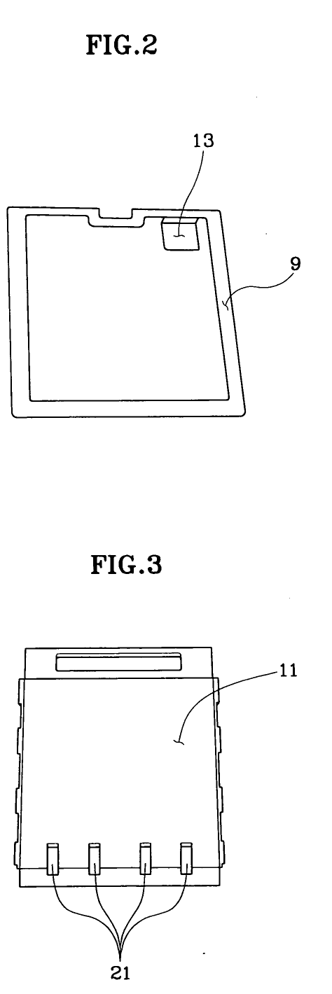

As illustrated in FIG. 1, PAM 3 of CDMA modem 1 is a heat-producing electronic element to be cooled. The CDMA modem 1 shown comprises an inner circuit substrate 5 and an external circuit substrate 7. However, the present invention can be applied to a modem or other electronic component with a single circuit substrate. In this embodiment, a single inner circuit substrate is shown, but there may be a plurality of inner circuit substrates.

As shown in FIG. 1, the structure of the CDMA modem 1 according to the embodiment of the present invention comprises an inner baffle 9, a baffle case 11, an inner circuit substrate 5, an extended portion 13, a PAM 3, and a radiating plate 17. The PAM 3 is mounted on the inner circuit substrate 5 and is a heat-producing electronic element. The object of the present invention is the transfer of heat produced by the PAM 3 away from the CDMA modem 1. The extended portion 13 is an extension of the inner baffle 9 and contacts the upper surface of the PAM 3. The baffle case surrounds the inner baffle 9. There is a plurality of holes 15 through the inner circuit substrate 15 underneath the PAM 3 and a plurality of holes 21 through baffle case 11. Radiating plate 17 is mounted on the baffle case 11 on the side of inner baffle 9 opposite the external circuit substrate 7.

The bottom surface of the baffle case 11 contacts a heat sink surface 19 on the upper surface of the external circuit substrate 7. The external circuit substrate 7 includes a plurality of external circuit substrate through holes 23 that align with the baffle case holes 21 through the baffle case 11.

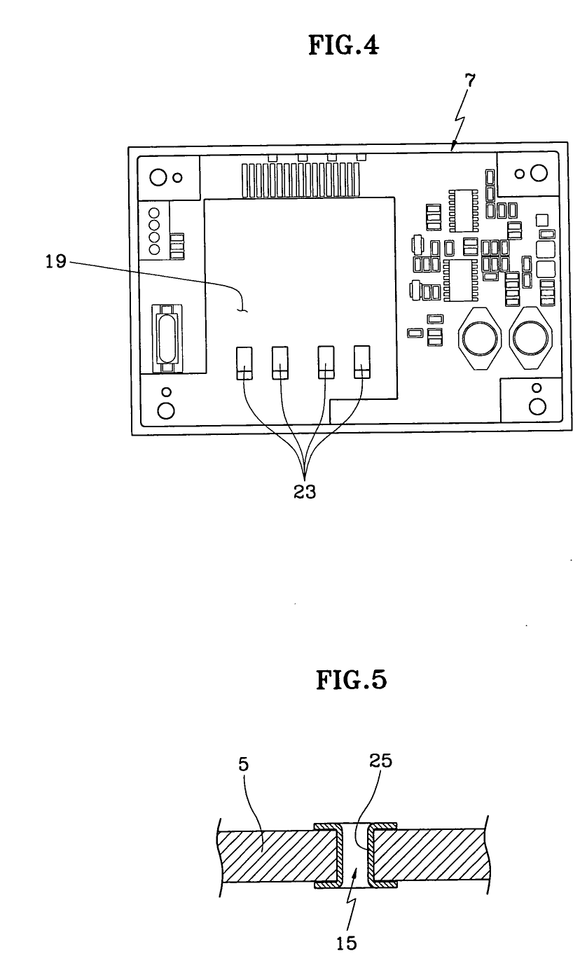

As shown in FIG. 4, the heat sink 19 is a flat surface made of lead or other appropriate heat-conducting material formed on the external circuit substrate 7 and may be applied to the external substrate 7 by an open mask soldering process.

Next, the cooling of the CDMA modem 1 having the structure thus described will be explained.

The extended portion 13 of the inner baffle 9 may directly contact the upper surface of the PAM 3 to allow transfer of the heat generated by the PAM 3 by means of conduction.

In addition, heat from the PAM 3 is discharged underneath the inner circuit substrate 5 via the through the holes 15 formed at the inner circuit substrate 5. As illustrated in FIG. 5, the holes 15 are lined with metal cylinders which electrically connect the upper and lower sides of the inner circuit substrate 5 and also act as media for transferring the heat generated by the PAM 3.

Heat from the PAM 3 passing through the extended portion 13 of the inner bafflement 9 is transferred through the baffle case 11 to the radiating plate 17. The surrounding air then conducts heat from a plurality of fins on the radiating plate 17. Heat from the PAM 3 is also transferred from the baffle case 11 via the through holes 15 of the inner circuit substrate 5 and via the heat sink 19. Hot air within the baffle case may then pass through holes 21 and 23 to transfer heat by convection.

Two of the paths of conductive heat transfer will now be described. Heat may be transferred through a path formed by the PAM 3, the extended portion 13, the inner baffle 9, the baffle case 11, and the radiating plate 17. Heat may also be transferred through a path formed by the PAM 3, the extended portion 13, the inner baffle 9, the baffle case 11, and the metal cooling surface 19 of the external circuit substrate 7.

A convective route of heat transfer is the PAM 3, the through holes 15, the baffle case holes 21, and the external circuit substrate holes 23.

Application of the various cooling means thus described prevents the PAM 3 from exceeding the stable operating temperature, thus providing a normal operating condition at all times and, more particularly, avoids the requirement of forced cooling means such as a fan. By avoiding the requirement of a fan, the life of the electronic components is not limited by the life expectancy of a fan or other source of forced cooling means. The present invention further prevents damage to circuits caused by inflow of dust during a long period of use.

As is obvious from the foregoing, there is an advantage in the cooling structure of an electronic element thus described according to the present invention in that an efficient heat transfer can be carried out via a variety of heat transfer routes of conduction and convention without recourse to a forced cooling means such as a fan or the like, thus improving the performance of electronic elements and stabilizing the operation of electronic circuits for an extended period.

1. A cooling structure for an electronic element, wherein the structure comprises:
an extended portion formed on an inner baffle and contacting an upper surface of a heat-producing electronic element, wherein the inner baffle and the heat-producing electronic element are mounted on an inner circuit substrate;
a plurality of through holes formed on the inner circuit substrate underneath the heat-producing electronic element;
a baffle case surrounding the inner baffle, the extended portion, the heat-producing electronic element, and the inner circuit substrate, the baffle case having an upper side and a lower side;
a radiating plate mounted on the upper side of the baffle; and
a plurality of baffle case holes through the lower side of the baffle case.

2. The structure as defined in claim 1 further comprising:
an external circuit substrate with an upper side and a lower side, wherein the upper side of the external circuit substrate further comprises a heat sink contacting the lower side of the baffle case; and
a plurality of external circuit substrate holes through external circuit substrate to correspondingly communicate with said baffle case holes of said baffle case.

3. The structure as defined in claim 2, wherein the heat sink is a flat surface made of metal formed on said external circuit substrate by a open mask soldering process.

4. The structure as defined in claim 3, wherein the metal is lead.

5. The structure as defined in claim 1, wherein the electronic element is a power amplifying module of a code division multiple access modem.
